(19) United States
(12) Patent Application Publication
(10) Pub. No.: US 2025/0085371 A1
(43) Pub. Date: Mar. 13, 2025

(54) Gradient Delay Time Correction

(71) Applicant: Siemens Healthineers AG, Forchheim (DE)

(72) Inventors: Christian Meixner, Erlangen (DE); Simon Bauer, Egolsheim (DE); Max Müller, Erlangen (DE); Dominik Paul, Bubenreuth (DE); Marcel Dominik Nickel, Herzogenaurach (DE); Michael Köhler, Nuernberg (DE)

(73) Assignee: Siemens Healthineers AG, Forchheim (DE)

(21) Appl. No.: 18/882,910

(22) Filed: Sep. 12, 2024

(30) Foreign Application Priority Data
Sep. 13, 2023 (DE) 10 2023 208 897.5

(51) Int. Cl. G01R 33/48; G01R 33/56; G01R 33/565

(52) U.S. Cl. CPC G01R 33/4826; G01R 33/5608; G01R 33/56518

(57) ABSTRACT

A computer-implemented method for gradient delay time correction of MR data using an MR device, wherein the magnetic resonance data is recorded using a three-dimensional recording technique with linear recording trajectories which are oriented in different readout directions of a readout plane that is perpendicular to a partition direction. The method includes: in a calibration measurement using the magnetic resonance device, recording calibration data which describes readout-direction-dependent shifts, caused by delay effects, of measurement points in the k-space; determining correction data by evaluating the calibration data; correcting the MR data based on the correction data in order to compensate for the delay effects, wherein the calibration data, which covers a coverage region in partition direction is recorded in a resolved manner, and the correction data is determined and applied in a manner that is dependent on partition direction.

### TECHNICAL FIELD

The disclosure relates to a computer-implemented method for gradient delay time correction of magnetic resonance data by means of a magnetic resonance device, wherein for the purpose of recording the magnetic resonance data, use is made of a three-dimensional recording technique with linear recording trajectories, which are oriented in different readout directions of a readout plane that is perpendicular to a partition direction, wherein
in a calibration measurement by means of the magnetic resonance device, calibration data is recorded, which describes readout-direction-dependent shifts caused by delay effects of measurement points, in particular, sampled k-space sections, in the k-space,
correction data is determined by evaluating the calibration data, and
the magnetic resonance data is corrected on the basis of the correction data in order to compensate for the delay effects.

In addition to this, the disclosure relates to a magnetic resonance device, a computer program, and an electronically readable data medium.

### BACKGROUND

Magnetic resonance imaging has become a standard imaging modality, particularly in the medical field. While recording trajectories that allow Cartesian sampling of the k-space are commonplace and routinely used, non-Cartesian recording trajectories are also now being proposed. One advantage of non-Cartesian sampling of the k-space is the lower susceptibility to movement and flow artifacts, particularly in the case of so-called radial sampling methods, in which radial recording trajectories, so-called radial spokes, are used, which pass through the k-space center at different angles. The k-space center is repeatedly and continuously sampled in this way. Ghosting artifacts are avoided. This results, for example, in a star-shaped sampling model. If a three-dimensional measurement is performed, a so-called stack of stars is produced, and partitions, i.e., thin slices, which are sequentially disposed of in a partition direction, can be reconstructed. The plane which is perpendicular to the partition direction and in which the recording trajectories are arranged in the shape of a star is referred to as a readout plane in the same way as other three-dimensional radial sampling models. The axes of an orthogonal coordinate system spanning the readout plane can be referred to as x- and y-axes, the partition direction then being defined by a z-axis. These axes can correspond to physical gradient directions or gradient axes, though this is not generally the case. Logical gradient axes can then be used.

Eddy currents that are generated by gradient pulses can result in temporally and spatially variable field interferences in magnetic resonance devices. Eddy currents that generate a spatially variable magnetic field in the direction of a readout gradient can have an influence on the actual echo time (TE), which represents the zero crossing of the effective gradient moment in the readout direction. Since the generated eddy currents are generally dependent on the direction of the gradient pulse that generates them, they can also modify the echo time to varying degrees as a function of the direction of the readout gradient (readout direction).

Other effects can likewise give rise to such delay times, or in general terms, delay effects, e.g., imperfections in the magnetic resonance device, in particular, the gradient system itself.

In the case of non-Cartesian sampling models, which use linear recording trajectories in different readout directions, in particular, therefore, radial sampling, it is also possible in particular for recording trajectories to occur that are traversed in a manner that is at least substantially contra-oriented, whereby the delay effects cause a problem in respect of the image quality in the readout plane (in-plane). In particular, the delay effects give rise to k-space shifts, such that the measured magnetic resonance data of the k-space is shifted by varying amounts depending on the readout direction or orientation in which the recording trajectory is traversed, such that it exhibits inconsistencies. This can give rise to various artifacts, such as ghosting or local signal obliterations. With regard to the recording trajectories which are traversed in a contra-oriented manner (contra-oriented recording trajectories), it should also be noted that these are characterized by opposing polarities of the respective gradient pulses.

It has therefore been proposed in the prior art to apply a delay time correction (DTC) in which corresponding correction data, obtained from calibration data, is averaged in partition direction or is calculated solely for the central partition.

In this case, the determination of the correction data and the derivation of corresponding correction values, e.g., k-space shifts and/or delay times (DT), are based on a recording of calibration data that describes these delay effects, in particular, k-space shifts. It has therefore been proposed, e.g., to measure contra-oriented recording trajectories in at least two readout directions, in particular exactly two readout directions, as calibration data in a calibration measurement. The two readout directions can describe the base of a Cartesian coordinate system and correspond to physical and/or logical gradient axes in the readout plane, for example. For each of these calibration readout directions, the gradient pulses are therefore output once with positive and once with negative polarity, a k-space shift which corresponds to the delay time (corresponds to the offset of the actual echo times) between the calibration scans with different polarity being determined for each calibration readout direction. Using this correction data and a mathematical correlation, k-space shifts (or delay times) can be derived for any readout directions in the readout plane. In particular, it is thus possible to shift the sampled k-space sections of the magnetic resonance data within the context of the correction in such a way that a consistent overall image is produced, in particular before a Cartesian re-gridding.

An article by Tess Armstrong et al., “Free-Breathing Liver Fat Quantification Using a Multiecho 3D Stack-of-Radial-Technique”, Magn. Reson. Med. 79 (2018), Pages 370-382, examines the possibility of fat quantification using three-dimensional radial star sampling. For the purpose of correcting delay effects, in particular gradient imperfections and gradient deviations, it is proposed in this case to model various delays and eddy current effects as an effective gradient delay and to record opposed calibration spokes at angles of 0 and π, as well as π/2 and 3π/2 and to compare these by means of cross-correlation, in order to determine k-space shifts on the basis of effective gradient delay effects. Averaging is applied along the partition direction. By means of mathematical correlation, k-space shifts for each spoke were determined from the calibration k-space shifts during the recording of the magnetic resonance data, and used for correction.

In an article by K. T. Block and M. Uecker, “Simple Method for Adaptive Gradient-Delay-Compensation in Radial MRI,” Conference Paper ISMRM 2011, Montreal, for the purpose of specifically evaluating pairs of calibration data sets for recording trajectories that run in a contra-oriented manner, it is proposed to fold these relative to the readout direction in order to perform the cross correlation. It is, however, specifically proposed not to locate the peak of the cross-correlation function but, in order to achieve greater precision, to determine the shift from the rise in the signal phase by means of linear regression. In this way, parts of the Fourier-transformed calibration data sets that lie outside the examination object and, therefore, have no defined phase are removed from the study.

### SUMMARY

The object of the disclosure is to improve the image quality of magnetic resonance recordings with respect to gradient delay effects.

In order to achieve this object, provision is made for a computer-implemented method, a magnetic resonance device, a computer program, and an electronically readable data medium as claimed in the independent patent claims. Advantageous developments are specified in the subclaims.

In a method of the type cited in the introduction, provision is inventively made for
the calibration data which covers a region of coverage in partition direction, in particular, that region covered by the recording of the magnetic resonance data, to be recorded in a resolved manner in partition direction, and for
the correction data to be determined and applied in a manner that is dependent on partition direction.

In the context of the present disclosure, it was found that as a result of spatially varying eddy currents in partition direction, delay effects can experience a variation over a three-dimensional volume, in particular, a stack of partitions. For example, magnetic resonance devices have been proposed in which hollow lines are used to transport cooling agents for the gradient coils, said hollow lines resulting in highly localized eddy currents which are also relevant in partition direction. If variations of the delay effects, i.e., in particular delay times or k-space shifts, along the partition direction are not taken into consideration, this can also cause reductions in the image quality.

According to the disclosure, an approach is therefore proposed that also takes into consideration the dependency of the artifacts, triggered by delay effects in the gradients, on the partition direction. It is therefore proposed to provide the correction in a resolved manner in partition direction and, therefore, to apply the correction in a suitably varied manner over the partition direction. To this end, the calibration data is also recorded in a resolved manner in partition direction, and a partition-dependent calculation of the correction data is performed on the basis of this calibration data. In this case, the delay effects comprise at least the field changes resulting from eddy currents but can also describe further causes in a model of various effects resulting in shifts.

As a result of the additional resolution of the correction in partition direction, it is possible significantly to reduce spatially varying eddy current effects, thereby improving the image quality of the magnetic resonance data or magnetic resonance image data sets reconstructed therefrom. The partition resolution of the artifacts that are caused by gradient delay effects, in particular eddy currents, is addressed and taken into consideration.

The correction is applied to the recorded magnetic resonance data, e.g., before Cartesian re-gridding in the readout plane. Adaptation of a recording protocol, in particular a magnetic resonance sequence with which the magnetic resonance data is recorded, cannot be partition-specific due to the simultaneous excitation of the three-dimensional volume.

Specifically, provision can be made for radial spokes, in particular offset by the golden angle, to be sampled using the recording technique, in particular for the purpose of generating a stack of stars. As stated in the introduction, radial sampling techniques are already known from the prior art and advantageously result in less sensitivity to movement. If radial spokes through the k-space center are studied, a three-dimensional measurement results in a star-shaped measurement for each partition (stack of stars). Particularly good sampling of the k-space is obtained if the golden angle is present between consecutively measured readout directions or spokes.

Calibration data is appropriately recorded for different partitions in partition direction, in particular the partitions that are also used during the recording of the magnetic resonance data. Partition-specific correction data can then be determined for each of these partitions and used for the correction. This means that the correction options are directly available for the partitions that are used during the three-dimensional measurement of the magnetic resonance data since they can be determined specifically for these.

In a particularly advantageous development of the present disclosure, provision can be made, e.g., to record the calibration data for at least two calibration readout directions, in particular spanning an orthogonal coordinate system in the readout plane in the k-space, in such a way that a k-space section of the respective readout direction is traversed in contra-oriented calibration recording trajectories. In this case, the calibration data of each calibration readout direction is evaluated for the purpose of determining a k-space shift, this being dependent on the partition in partition direction in the position space, of the calibration recording trajectories in opposing directions for each partition covered by the calibration data in partition direction. The k-space shifts (which correspond directly to the delay time and can also be determined as such) determined thus for the various partitions form the correction data. Therefore, the approach discussed in the prior art, e.g., in the articles cited in the introduction, is also used in this preferred exemplary aspect, but in this case, the evaluation takes place individually for each partition. This means that direct correction data is available for each partition of the three-dimensional measurement of the magnetic resonance data.

In particular, it has been shown that measuring along two calibration readout directions is sufficient for the correction, and therefore recording time for the calibration data can be saved by a corresponding restriction. The calibration readout directions, in this case, can correspond to, e.g., logical gradient axes in the readout plane, e.g., to an x-direction and a y-direction, correspondence to physical gradient axes being conceivable likewise.

At this point, it should be noted generally that in the case of partition-based evaluation, in order to determine correction data for the various partitions of the magnetic resonance data, a larger amount of calibration data can be recorded than in cases where averaging takes place in partition direction. In this case, for the purpose of recording the calibration data, a three-dimensional sampling model is preferably used again in order to remain as close as possible to the recording of the magnetic resonance data.

In order to determine k-space shifts for further readout directions of the readout plane, which do not correspond to one of the calibration readout directions, the k-space shifts of the calibration readout directions can be geometrically combined according to a mathematical correlation. Suitable formulas are disclosed, e.g., in the two articles by Block et al. or Armstrong et al. cited in the introduction.

Specifically, for the purpose of determining the correction data for each calibration readout direction, provision can be made for the calibration data of both contra-oriented calibration recording trajectories in partition direction to be Fourier-transformed for distribution over partitions in the position space, whereupon for each partition
the calibration data profiles for the calibration recording trajectories are cross-correlated in order to determine a shift in the position space, and
the k-space shift associated with the greatest correlation is determined.

In order to allow the assignment to partitions defined in the position space, a Fourier transformation can first take place in partition direction so that the calibration data is then present in a combination space in which it is ideally also possible for the correction to take place as explained in further detail below. Following the distribution of the calibration data over the partitions, the cross-correlation then takes place in order to determine the k-space shift with greatest correlation. The cross-correlation can be performed here, e.g., by mirroring the calibration data profile of one of the directions, determining a cross-correlation function, in particular by means of folding with Fourier transformation in the calibration readout direction, and specifying the maximum thereof as the k-space shift concerned. It is, however, particularly preferred, as per, e.g., the publication by Block et al. cited above, to determine the shift with greater precision from the rise of the signal phase using linear regression, the evaluation is appropriately limited to the examination object along the calibration readout direction.

For the purpose of correcting the delay effects in the magnetic resonance data, provision can be made in a specific aspect as follows:
the magnetic resonance data is Fourier-transformed for assignment to partitions in partition direction,
a correction k-space shift is determined from the correction data as a correction value for each readout direction and partition that is used for recording the calibration data, and
the magnetic resonance data, which has been Fourier-transformed in partition direction, in particular before Cartesian re-gridding in the readout plane, is shifted according to the respective correction k-space shifts.

Therefore, the correction likewise can take place in a sort of intermediate space in which the Fourier transformation with respect to the partition direction has already been performed, and the assignment to partitions in the position space is therefore possible. The correction can, therefore, take place in the readout plane (still in the k-space) with a specific correction value, a k-space shift here, per partition/slice.

Such three-dimensional measurements of magnetic resonance data are generally made using a local coil arrangement comprising local coils that are positioned on or around the examination object, e.g., a patient or an examination phantom. This means that the magnetic resonance data is measured using a plurality of receive channels. For the calibration data, likewise, provision can be made for recording this using a plurality of receive channels (e.g., of the same local coil arrangement).

Tests in the context of the present disclosure have however shown that objects or parts of the examination object in the peripheral measuring field, which are located outside or at the edge of the homogeneity volume of the magnetic resonance device in partition direction, can lead to very high correction values, e.g., k-space deviations and delay times. This, in turn, can result in an overcorrection. The reasons for this can be many and diverse, e.g., artifacts in the dimensioning of the calibration data and/or significant spatial variations in the magnetic and gradient fields and in the send and receive profiles at the edge of the homogeneity volume that can be used for imaging. It is evident in particular that receive channels of local coils assigned to such parts of the examination object can exhibit erroneous behavior accordingly.

Various aspects of the inventive method are proposed to solve this problem, and in this regard allow an improvement of the image quality and a reduced interference effect of faulty receive channels.

Provision can, therefore, be made for correction values, in particular k-space shifts and/or delay times, which can be determined for the receive channels in the context of correcting the delay effects, to be limited by means of a lowest permissible minimum value and/or a highest permissible maximum value. A means that can easily be implemented is thereby provided in order to avoid overcorrections. The maximum and/or minimum correction values are limited. In principle, an empirical specification of suitable minimum values and/or maximum values is conceivable in this case. It has, however, proven advantageous, in the case of receive channel-specific evaluation of the calibration data for the purpose of determining the correction data, to
determine receive channel-specific evaluation values corresponding to correction values, in particular for the calibration readout directions, and
to determine the minimum value and/or the maximum value by means of statistical processing of the evaluation values, in particular, to determine the maximum value as an average or median of the evaluation values.

Tests show that the average or the median over all receive channels as a minimum value and/or maximum value, in particular as a maximum amount of the respective correction direction, already shows clear advantages in respect of the image quality.

Additionally, or alternatively, provision can be made to identify by means of an identification condition, in particular, which uses statistical processing of receive channel-specific evaluation values, receive channels that have measurement results that deviate excessively, and ignore said channels when determining the correction data. It is, therefore, possible to exclude receive channels that provide implausible or erroneous calibration data from the determination of the correction data. In particular, it is possible to remove from the study those receive channels that result in a correction value that deviates significantly from other receive channels, e.g., a significantly deviating k-space deviation and/or a significantly deviating delay time. Such outliers can be identified in particular via a or the statistical analysis, in particular by means of comparison with a standard deviation or a median, in the identification condition. Suitable threshold values in the identification condition can be determined, e.g., empirically and/or predetermined on the basis of a theoretical analysis. Such an exclusion of receive channels appropriately takes place before any averaging over the receive channels, which in specific exemplary aspects can take place before the cross-correlation or also after the cross-correlation.

In a particularly preferred alternative approach, provision can also be made for the calibration data to be recorded using a whole-body coil of the magnetic resonance device and for the magnetic resonance data to be recorded using a local coil arrangement having a plurality of receive channels. This can also be effective if the whole-body coil (body coil) has a plurality of receive channels from which an average can be taken. The use of the whole-body coil to determine the correction data is advantageous in that the whole-body coil generally has a receive profile which is more homogenous than that of local coil elements. It is thereby possible to avoid or at least reduce artifacts and problems associated with masking or averaging due to spatially widely varying receive profiles. The correction data determined by means of the whole-body coil can then be applied to the magnetic resonance data of the local coil arrangement.

Appropriate exemplary aspects, when evaluating calibration data for the purpose of determining correction data, can provide for masking of the calibration data to be performed in the position space in order to exclude regions that are not covered by a recorded examination object and/or peripheral parts of the examination object, in particular parts which are located at the edge of or outside a homogeneity volume of the magnetic resonance device. Such masking can also have an advantageous effect with regard to negative influences of parts of the examination object that are arranged peripherally in partition direction. In addition, a restriction to regions that actually show an examination object can also be appropriate in the case of approaches as discussed above in which the cross correlation and the specification of the k-space shift take place on the basis of the phase. For example, it is conceivable in this context additionally to omit even larger regions of the examination object in partition direction, e.g., the arms of a patient, from the study when determining the correction data in order to obtain a more reliable set of data.

In addition to the method, the present disclosure also relates to a magnetic resonance device having a control device that is designed to perform the inventive method. All of the explanations concerning the inventive method can be transferred analogously to the inventive magnetic resonance device, such that the advantages previously cited can also be obtained thereby.

The control device preferably has at least one processor and at least one storage means. Functional components can take the form of hardware and/or software in order to control the operation of the magnetic resonance device and allow the performance steps of the inventive method and developments thereof. For example, the control device can have a recording unit (sequence unit) in order to control the recording of the calibration data and the magnetic resonance data as well as other recording processes. The control device can also have:
an evaluation unit for evaluating the calibration data in order to determine the correction data, said correction data being determined in a manner that is dependent on partition direction, and
a correction unit for correcting, in a manner that is dependent on partition direction, the magnetic resonance data on the basis of the correction data in order to compensate for the delay effects.

Further functional units and subunits of the cited functional units can be provided in order to implement developments of the present disclosure.

A computer program, according to the disclosure, can be loaded directly into a storage means of a control device of a magnetic resonance device and has program means such that execution of the computer program on the control device causes the control device to perform the steps of a method according to the disclosure. The computer program can be stored on an electronically readable data medium according to the present disclosure, such that said data medium has control information stored thereon, which comprises at least one computer program according to the disclosure and is embodied such that when the data medium is used in a control device of a magnetic resonance device, this is developed to perform a method according to the disclosure. The electronically readable data medium can be a non-transient data medium in particular, e.g., a CD-ROM.

### BRIEF DESCRIPTION OF THE DRAWINGS

Further advantages and details of the present disclosure are derived from the exemplary aspects described in the following and with reference to the drawings, in which:

FIG. 1 schematically shows a possible profile of a delay time in partition direction,

FIG. 2 shows a flow diagram of an exemplary aspect of the method according to the disclosure,

FIG. 3 shows a schematic diagram of a magnetic resonance device according to the disclosure, and

FIG. 4 shows the functional structure of a control device of the magnetic resonance device.

### DETAILED DESCRIPTION

Exemplary aspects of the disclosure for recording magnetic resonance data using a magnetic resonance device are explained in the following. In this case, the magnetic resonance data is recorded using a three-dimensional recording technique in accordance with a recording protocol, in particular in a single magnetic resonance sequence, in which non-Cartesian sampling of the k-space takes place. The present exemplary aspects relate to a radial stack-of-stars sampling, in which recording trajectories extending in a readout plane, so-called radial spokes, intersect in the center of the k-space. For the readout time periods assigned to these recording trajectories, which extend in different readout directions, gradient pulses are applied in the readout plane, while the spatial resolution in the partition direction perpendicular to the readout plane is affected by means of a phase encoding (outside the readout time period).

As a result of various delay effects relating to the gradients, the recording trajectories can deviate from the recording trajectories originally desired in the design of the magnetic resonance sequence, such that the echo times deviate likewise. These delay effects act differently, in particular on k-space sections, which run in different orientations along the readout directions, and therefore, an inconsistent set of k-space data can be produced overall. While various, in particular all, delay effects relating to the gradients are usually modeled for an overall time delay correction, the inconsistencies that occur in the case of different readout directions and orientations are primarily caused by eddy currents, which can arise in metallic components of the magnetic resonance device such as hollow lines for cooling agents, for example.

Corrections that average over the partition direction or which only study a representative (e.g., central) partition are already known from the prior art, in which a correction value, e.g., a k-space shift or a delay time, can be derived from correction data as a function of the readout direction in the readout plane, said correction data having been determined on the basis of calibration data, e.g. for two calibration readout directions forming a right-angled coordinate system in the readout plane.

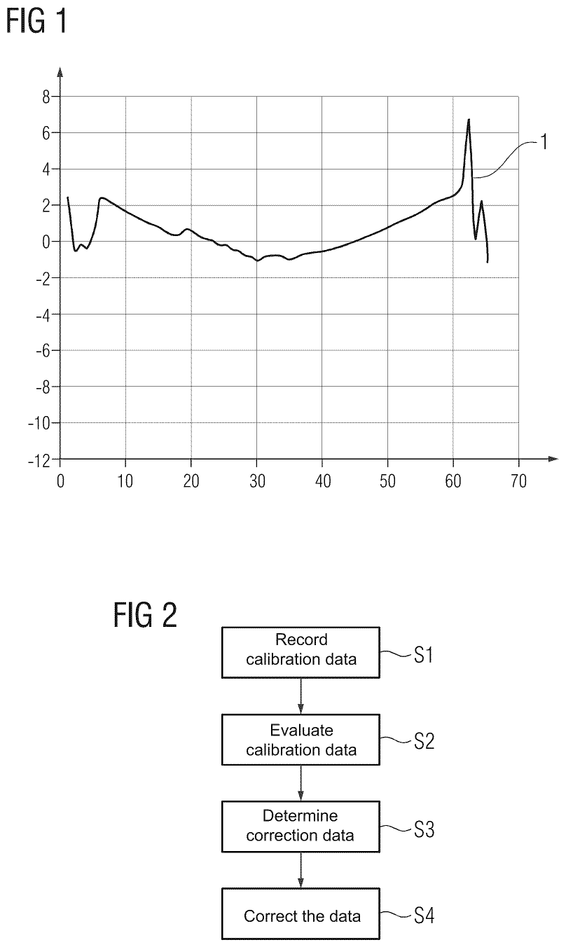

It is, however, now evident that the delay effects also vary in the partition direction very significantly in some magnetic resonance devices, consequently resulting in loss of image quality, in particular artifacts, if the correction only takes place as a function of the readout direction in the readout plane. By way of example, FIG. 1 shows a profile 1 of delay times that occur in partition direction as a result of delay effects for a specific receive channel in the example. In this case, the x-axis shows the location in partition direction in suitable units, while the y-axis shows the delay time in units of the sampling time of the ADC during the recording (dwell time). It can be seen that the delay time varies in the range from approximately −0.5 to 2.5 dwell times. In this context, the drop at the edge (which also corresponds to the edge of the homogeneity volume and can relate to the arms, for example) is not accurate but is caused by signal enhancement effects in individual local coil elements of the local coil arrangement.

It is therefore proposed not only to measure the calibration data in a resolved manner in partition direction but also to specify the correction data from the calibration data in a resolved manner in partition direction so that it is possible, in particular for different partitions in partition direction, to determine and apply different correction values, in particular k-space shifts and/or delay times, in order to perform the correction. In the exemplary aspects shown here, the correction takes place after the recording of the magnetic resonance data, in particular before a Cartesian re-gridding in the readout plane.

FIG. 2 shows a flow diagram of an exemplary aspect of the method according to the disclosure. In this case, the calibration data is recorded in a step S1, this being possible on the one hand by means of the local coil arrangement, which is also used to record the magnetic resonance data, but on the other hand, is preferably affected by means of a whole-body coil of the magnetic resonance device since this has a more homogenous receive profile, meaning that e.g. the problems of faulty measurements associated with peripheral receive channels can be at least reduced.

For the purpose of recording the calibration data, use is also made of the three-dimensional recording technique that is used for the magnetic resonance data. This means, in particular, that calibration data is recorded in a resolved manner in partition direction, in particular for the region that is also covered by the magnetic resonance data in partition direction. In exemplary aspects, the resolution in partition direction can correspond to that used for the recording of the magnetic resonance data so that the calibration data is then present for the same partitions as the magnetic resonance data.

As calibration data in the specific exemplary aspect according to FIG. 2, two calibration readout directions are sampled with opposed orientation, meaning that corresponding contra-oriented calibration recording trajectories are used in respect of a specific k-space section. The calibration readout directions, in this case, extend over an orthogonal coordinate system in the readout plane and can correspond to physical and/or logical gradient axes, e.g., an x-direction and/or a y-direction. The partition direction then corresponds to the z-direction.

In other words, each of the two calibration readout directions is traversed in both possible orientations, thereby producing a pair of calibration readout trajectories relative to the coordinate system, with angles of 0° and 180° (π) (e.g. for the x-direction as readout direction) and a further pair of calibration readout trajectories with angles of 90° (π/2) and 270° (3π/2) (e.g. for the y-direction as readout direction).

The recording of the calibration data can preferably take place immediately before the recording of the magnetic resonance data.

In a step S2, the evaluation of the calibration data begins by means of a Fourier transformation of the calibration data for each calibration recording trajectory along the partition direction. This makes it possible to assign the received calibration data, which is in the readout plane and still present in the k-space, to various partitions in partition direction in the position space, preferably to those partitions that are also provided for the magnetic resonance data.

In a step S3, the sorted calibration data is evaluated for each partition and for each calibration readout direction in order to determine correction data, specifically k-space shifts, for each calibration readout direction. To this end, the profiles of each of the pairs in the respective calibration readout direction are cross-correlated, and the k-space shift with the greatest cross-correlation is ascertained. These k-space shifts with the greatest cross-correlation then form the correction data or part thereof.

In order to actually perform the cross-correlation, provision can be made for mirroring the calibration data profile of one of the calibration recording trajectories, which is traversed in a contra-oriented manner, then performing a Fourier transformation along the readout direction and determining an intermediate function in the position space by multiplying the one calibration data profile with the other complex-conjugated calibration data profile. While the Fourier transform of this intermediate function forms the cross-correlation function, and it is possible to specify the maximum thereof that is present in the k-space concerned, a more precise approach is preferred, which evaluates the rise of the phase, as described in the article cited in the introduction by Block et al. In this context, in particular, masking of the calibration data can take place on the examination object itself, in which case parts of the examination object, e.g., the arms of a patient, can also be masked out because the measurement is less accurate in the peripheral region in partition direction.

Following the step S3, k-space shifts are therefore available for every partition and for the calibration readout directions.

It should be noted at this point that if the calibration data was not recorded using the whole-body coil but with the local coil arrangement in a plurality of receive channels, measures can be provided to reduce the described peripheral effects or their influence on the correction, and in particular to avoid overcorrections. Using an identification condition, for example, erroneous receive channels or receive channels whose calibration data produces a k-space deviation that deviates excessively from the other receive channels can be identified and excluded before the study, e.g., by means of statistical analysis. It is moreover also conceivable when determining the correction data already to define a maximum value and/or a minimum value that must not drop below or be exceeded by correction values, in particular k-space shifts, that are specified for the correction. The minimum value and the maximum value can be determined in a statistical analysis of the k-space shifts of the various receive channels, e.g., limited to non-excluded receive channels, with, e.g., the average or the median over the receive channels shown to be a useful maximum or minimum value.

The correction of the magnetic resonance data then takes place in the step S4. In order to achieve this, correction values are determined for each partition of the magnetic resonance data and each readout direction of the magnetic resonance data. A correction k-space shift is determined as a correction value for the readout directions by means of a geometric mathematical correlation from the correction data for the corresponding partition, cf., e.g., the article by Armstrong et al. and Block et al. cited above. The magnetic resonance data, which is already Fourier-transformed in the partition direction and can therefore be assigned to the partitions but is still present in the k-space in the readout plane, is adapted on the basis of the correction k-space shifts in such a way that a consistent overall image is produced.

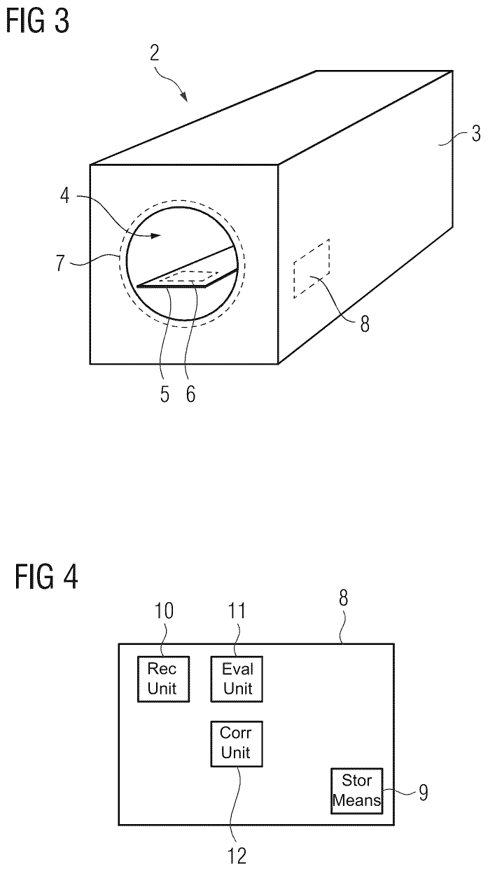

FIG. 3 shows a schematic diagram of a magnetic resonance device 2 according to the disclosure, comprising a main magnet unit 3 with a cylindrical patient receiving region 4 as per known principles. A patient table 5, on which is indicated a local coil arrangement 6 that can be used to record the magnetic resonance data (and also the calibration data if applicable), can be moved into the patient receiving region 4. Surrounding the patient receiving region 4 but not shown in detail here are a gradient coil arrangement and a high-frequency coil arrangement which forms a whole-body coil 7. The calibration data can preferably be recorded using the whole-body coil 7.

The operation of the magnetic resonance device 2 is controlled by a control device 8, which is also designed to carry out the inventive method.

FIG. 4 shows a functional diagram of the structure of the control device 8. In addition to a storage means 9, in which, e.g., calibration data, correction data, and magnetic resonance data can be stored at least periodically, the control device 8 also has a recording unit 10, which controls the recording operation of the magnetic resonance device generally, in particular by triggering the gradient coil arrangement and the whole-body coil 7 and/or the local coil arrangement 6 in accordance with a recording protocol, this comprising at least one magnetic resonance sequence. The recording unit 10 is also designed to record the calibration data in the step S1 and to record the magnetic resonance data.

The control device 8 further comprises an evaluation unit 11, in which the calibration data can be evaluated according to the steps S2 and S3 in order to determine the correction data.

The correction according to the step S4 can be performed in a correction unit 12.

Although the disclosure is illustrated and described in detail with reference to the preferred exemplary aspect, the disclosure is not restricted to the examples disclosed herein, and other variations may be derived therefrom by a person skilled in the art without departing from the scope of the disclosure.

Independent of the grammatical term usage, individuals with male, female, or other gender identities are included within the term.

1. A computer-implemented method for gradient delay time correction of magnetic resonance data using a magnetic resonance device, wherein the magnetic resonance data is recorded using a three-dimensional recording technique with linear recording trajectories which are oriented in different readout directions of a readout plane that is perpendicular to a partition direction, the computer-implemented method comprising:
in a calibration measurement using the magnetic resonance device, recording calibration data that describes readout-direction-dependent shifts, caused by delay effects, of measurement points in k-space;
determining correction data by evaluating the calibration data; and
correcting the magnetic resonance data based on the correction data in order to compensate for the delay effects,
wherein the calibration data, which covers a coverage region in a partition direction is recorded in a resolved manner in partition direction, and the correction data is determined and applied in a manner that is dependent on partition direction.

2. The computer-implemented method as claimed in claim 1, further comprising:
sampling radial spokes using the three-dimensional recording technique and/or recording calibration data for different partitions in partition direction.

3. The computer-implemented method as claimed in claim 1, further comprising:
recording the calibration data for at least two calibration readout directions such that a k-space section of the respective readout direction is traversed in contra-oriented calibration recording trajectories; and
evaluating the calibration data of each readout direction to determine a k-space shift, which is dependent on the partition in partition direction in a position space of the calibration recording trajectories in opposing directions for each partition covered by the calibration data in partition direction, wherein the k-space shifts form the correction data.

4. The computer-implemented method as claimed in claim 3, further comprising:
for determining k-space shifts for further readout directions of the readout plane, which do not correspond to one of the calibration readout directions, geometrically combining the k-space shifts of the calibration readout directions according to a mathematical correlation.

5. The computer-implemented method as claimed in claim 3, wherein for determining the correction data for each calibration readout direction, the calibration data of both contra-oriented calibration recording trajectories in partition direction is Fourier-transformed for distribution over partitions in the position space, whereupon for each partition:
cross-correlated calibration data profiles for the calibration recording trajectories are cross-correlated in order to determine a shift in the position space, and
the k-space shift associated with the greatest correlation is determined.

6. The computer-implemented method as claimed in claim 1, wherein for correcting the delay effects in the magnetic resonance data,
Fourier-transforming the magnetic resonance data for assignment to partitions in partition direction;
determining a correction k-space shift from the correction data for each readout direction and partition that is used for recording the calibration data; and
shifting the magnetic resonance data, which has been Fourier-transformed in partition direction, according to the respective correction k-space shifts.

7. The computer-implemented method as claimed in claim 1, wherein a plurality of receive channels are used during the measurement of the calibration data and the magnetic resonance data.

8. The computer-implemented method as claimed in claim 7, wherein correction values are limited using a lowest permissible minimum value and/or a highest permissible maximum value.

9. The computer-implemented method as claimed in claim 8, further comprising, during receive channel-specific evaluation of the calibration data for determining the correction data:
determining receive channel-specific evaluation values corresponding to correction values; and
determining a minimum value and/or a maximum value using statistical processing of the evaluation values.

10. The computer-implemented method as claimed in claim 7, further comprising:
using an identification condition, identifying and ignoring receive channels that have measurement results that deviate excessively when determining the correction data.

11. The computer-implemented method as claimed in claim 1, wherein the calibration data is recorded using a whole-body coil of the magnetic resonance device and the magnetic resonance data is recorded using a local coil arrangement comprising a plurality of receive channels.

12. The computer-implemented method as claimed in claim 1, wherein when evaluating calibration data for determining correction data, masking of the calibration data is performed in a position space in order to exclude regions that are not covered by a recorded examination object and/or peripheral parts of the examination object.

13. A magnetic resonance device, comprising:
a control device that is designed to carry out the computer-implemented method as claimed in claim 1.

14. A non-transitory electronically readable data medium storing a computer program which, when executed on a control device of a magnetic resonance device, causes the control device to perform the computer-implemented method as claimed in claim 1.
